(19) United States
(12) Patent Application Publication
(10) Pub. No.: US 2009/0212370 A1
(43) Pub. Date: Aug. 27, 2009

(54) SEMICONDUCTOR DEVICE HAVING INSULATED GATE FIELD EFFECT TRANSISTORS AND METHOD OF FABRICATING THE SAME

(75) Inventor: Hitoshi Ikei, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/388,781

(22) Filed: Feb. 19, 2009

(30) Foreign Application Priority Data
Feb. 21, 2008 (JP) 2008-040414

(51) Int. Cl. H01L 27/088; H01L 21/82

(52) U.S. Cl. 257/368; 438/197; 257/E27.06; 257/E21.602

(57) ABSTRACT

A semiconductor device has a plurality of insulated gate field effect transistors on a semiconductor substrate. A SAC contact hole is formed between two gates of the insulated gate field effect transistors. A side portion of the SAC contact hole is separated from two gates of the insulated gate field effect transistors by a side wall dielectric film and a dielectric film. A polycrystalline silicon plug having a U-shaped section structure is formed in a bottom portion of the SAC contact hole. A barrier metal film is formed on the polycrystalline silicon plug. A metal plug is buried on the barrier metal film so that covering on the SAC contact hole.

### CROSS REFERENCE TO RELATED APPLICATION

This application is based upon and claims the benefit of priority from the prior Japanese Patent Application No. P2008-40414, filed on Feb. 21, 2008, the entire contents of which are incorporated herein by reference.

### FIELD OF THE INVENTION

The invention relates to a semiconductor device having insulated gate field effect transistors and a method of fabricating the same.

### DESCRIPTION OF THE BACKGROUND

Along with the advancement in minituarization and integration density of semiconductor elements, the dimensions of a contact hole are becoming smaller. However, if variations in alignment of the contact hole with an underlying diffusion layer or an underlying wiring layer are taken into consideration, the dimensions of the contact hole are designed to be larger. Thus, self-aligned contact (SAC) independent of alignment accuracy, which is alignment performance, of an exposure apparatus, is frequently adopted for a semiconductor memory, a system LSI, and the like. SAC technology is disclosed in Japanese Patent Application Publication No. 2007-110088.

A memory cell transistor using the SAC technology is such that, as a technology node becomes finer, the contact dimensions of the memory cell transistor become correspondingly finer. This leads to the problems of increased contact resistance value and also widened variation range of the contact resistance.

### SUMMARY OF THE INVENTION

According to an aspect of the invention is provided a semiconductor device, comprising a first insulated gate field effect transistor formed on a semiconductor substrate of a first conductive type, a second insulated gate field effect transistor formed on the semiconductor substrate and having a gate being adjacent to a gate of the first insulated gate field effect transistor, a semiconductor layer of a second conductive type formed in a surface region of the semiconductor substrate between the gates of the first and the second insulated gate field effect transistors as a source or a drain of the first and the second insulated gate field effect transistors, and a contact plug composed of a polycrystalline silicon plug, a barrier metal film and a metal plug and formed in a contact hole, a side portion of the contact plug being separated from the gates of the first and the second insulated gate field effect transistors by a dielectric film, wherein the polycrystalline silicon plug has a U-shaped section structure and is formed in a bottom portion of the contact hole, and wherein the barrier metal film is formed on the polycrystalline silicon plug, and wherein the metal plug is formed on the barrier metal film.

According to another aspect of the invention is provided a semiconductor device, comprising a first insulated gate field effect transistor formed on a semiconductor substrate of a first conductive type, a second insulated gate field effect transistor formed on the semiconductor substrate and having a gate being adjacent to a gate of the first insulated gate field effect transistor, a semiconductor layer of a second conductive type formed in a surface region of the semiconductor substrate between the gates of the first and the gate of the second insulated gate field effect transistors as a source or a drain of the first and the second insulated gate field effect transistors, and a contact plug composed of a silicon plug, a barrier metal film and a metal plug in a contact hole, a side portion of the contact plug being separated from the gates of the first and the second insulated gate field effect transistors by a dielectric film, wherein the silicon plug has a pyramid—shaped section structure and is formed in a bottom portion of the contact hole, and wherein the barrier metal film is formed on the silicon plug, and wherein the metal plug is formed on the barrier metal film.

According to another aspect of the invention is provided a method of fabricating a semiconductor device, comprising forming a side wall dielectric film on a side of a gate of a first and a second insulated gate field effect transistors forming a dielectric film on a gate of the first and the second insulated gate field effect transistors, a side of the side wall dielectric film and a source or a drain of the first and the second insulated gate field effect transistors, forming a interlayer dielectric film on the dielectric film, forming a contact hole between a gate of the first insulated gate field effect transistor and a gate of the second insulated gate field effect transistor adjacent to the first insulated gate field effect transistor, forming a polycrystalline silicon film in a bottom portion of the contact hole and a side of the contact hole and on the interlayer dielectric film, forming a polycrystalline silicon film having a U-shaped section structure in a bottom portion of the contact hole as a polycrystalline silicon plug, by removing a portion of the polycrystalline silicon film formed on the interlayer dielectric film and another portion of the polycrystalline silicon film formed in a upper portion of the contact hole using a etch back process, forming a barrier metal film on the polycrystalline silicon plug, and burying a metal plug on the barrier metal film so that covering on the contact hole.

### BRIEF DESCRIPTION OF THE DRAWINGS

FIG. 1 is a cross-sectional view showing a semiconductor device according to a first embodiment of the invention.

FIG. 2 is a graph showing the relationship between the contact resistance and the technology node of a memory cell transistor according to the first embodiment of the invention.

FIG. 3 is a cross-sectional view for illustrating a fabrication process for the semiconductor device according to the first embodiment of the invention.

FIG. 4 is a cross-sectional view for illustrating the fabrication process for the semiconductor device according to the first embodiment of the invention.

FIG. 5 is a cross-sectional view for illustrating the fabrication process for the semiconductor device according to the first embodiment of the invention.

FIG. 6 is a cross-sectional view for illustrating the fabrication process for the semiconductor device according to the first embodiment of the invention.

FIG. 7 is a cross-sectional view showing a semiconductor device according to a second embodiment of the invention.

FIG. 8 is a cross-sectional view for illustrating a fabrication process for the semiconductor device according to the second embodiment of the invention.

FIG. 9 is a cross-sectional view showing a semiconductor device according to a third embodiment of the invention.

FIG. 10 is a cross-sectional view for illustrating a fabrication process for the semiconductor device according to the third embodiment of the invention.

FIG. 11 is a cross-sectional view for illustrating the fabrication process for the semiconductor device according to the third embodiment of the invention.

### DETAILED DESCRIPTION OF THE INVENTION

Embodiments of the invention will be described below in detail with reference to the drawings.

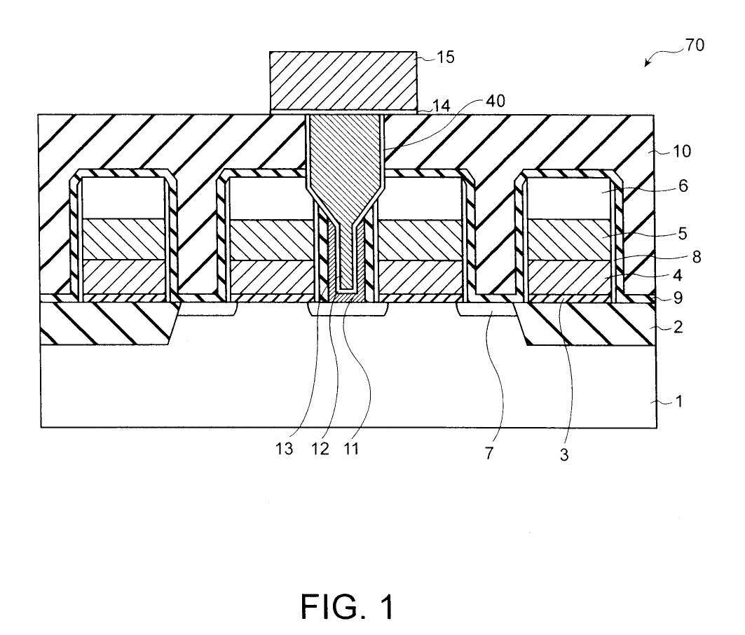

A semiconductor device according to a first embodiment of the invention and a method of fabricating the same will be described with reference to the drawings. FIG. 1 is a cross-sectional view showing the semiconductor device. In the first embodiment, a polycrystalline silicon plug having a U-shaped section structure is formed in a bottom portion of a SAC contact hole of a memory cell transistor.

As shown in FIG. 1, a semiconductor device 70 includes plural memory cell transistors formed on a semiconductor substrate 1. The semiconductor device 70 is a DRAM (dynamic random access memory) provided with the plural memory cell transistors and with a peripheral circuit and an input/output circuit (not shown). MIS transistors are used as transistors to form the peripheral circuit and the input/output circuit. An n channel type MIS transistor is used as the memory cell transistor. Incidentally, a MOS transistor may be used in place of the MIS transistor.

The MIS transistor may also be called MISFET (metal insulator semiconductor field effect transistor). The MOS transistor may also be called MOSFET (metal oxide semiconductor field effect transistor). The MIS transistor and the MOS transistor may also be called insulated gate field effect transistors.

The semiconductor device 70 includes a gate dielectric film 3, a gate electrode film 4, a metal silicide film 5, and a dielectric film 6, which are stacked on the semiconductor substrate 1 made of p type silicon. The gate dielectric film 3, the gate electrode film 4 and the metal silicide film 5 constitute a gate of the memory cell transistor. The gate dielectric film 3, the gate electrode film 4, the metal silicide film 5 and the dielectric film 6 are stacked on STI (shallow trench isolation) 2 buried in a first principal surface (or a top surface) of the semiconductor substrate 1 made of the p type silicon. The gate electrode film 4 and the metal silicide film 5 are used as wirings.

An n type diffusion layer 7 which is an n type semiconductor layer of the opposite conductive type to that of the semiconductor substrate 1 is formed in the top surface of the semiconductor substrate 1 between a gate dielectric film 3 and another gate dielectric film 3 and between the gate dielectric film 3 and the STI 2. A side wall dielectric film 8 is formed on the side of the stacked structure formed of the gate electrode film 4, the metal silicide film 5 and the dielectric film 6. A dielectric film 9 is formed on top of the n type diffusion layer 7, the STI 2 and the dielectric film 6 and on the side of the side wall dielectric film 8. An interlayer dielectric film 10 is formed on the dielectric film 9.

A SAC contact hole 40 is formed between the gates of the memory cell transistors. The formation of the SAC contact hole 40 is accomplished by etching the top portions of the dielectric film 6, the side wall dielectric film 8 and the dielectric film 9 and by removing the dielectric film 9 on the n type diffusion layer 7. The SAC contact hole 40 has a funnel-shaped section structure whose top portion is wider than the bottom portion. As employed herein, self-aligned contact (SAC) refers to the contact formed by self alignment process with the dielectric film 6, the side wall dielectric film 8 and the dielectric film 9 acting as a mask.

A contact plug constructed of a polycrystalline silicon plug 11, a barrier metal film 12 and a metal plug 13 is buried in the SAC contact hole 40. The polycrystalline silicon plug 11 is doped with an n type impurity. The polycrystalline silicon plug 11 is formed on top of the n type diffusion layer 7 and on the side of the dielectric film 9. The polycrystalline silicon plug 11 has a U-shaped section structure. The barrier metal film 12 is formed on the polycrystalline silicon plug 11 and on the side of the SAC contact hole 40. The metal plug 13 is buried in the SAC contact hole 40 and provided on the barrier metal film 12 so as to cover the SAC contact hole 40. A metal wiring 15 to be connected to a bit line is formed on the contact plug, and a barrier metal film 14 is formed in the bottom portion of the metal wiring 15.

Here, a memory cell is constituted of the memory cell transistor and a capacitor. Although not shown, the capacitor is connected to the n type diffusion layer 7 to which the SAC contact hole 40 of the memory cell transistor is not provided. The capacitor is formed in a trench portion in the top surface of the semiconductor substrate 1, or on top of the semiconductor substrate 1.

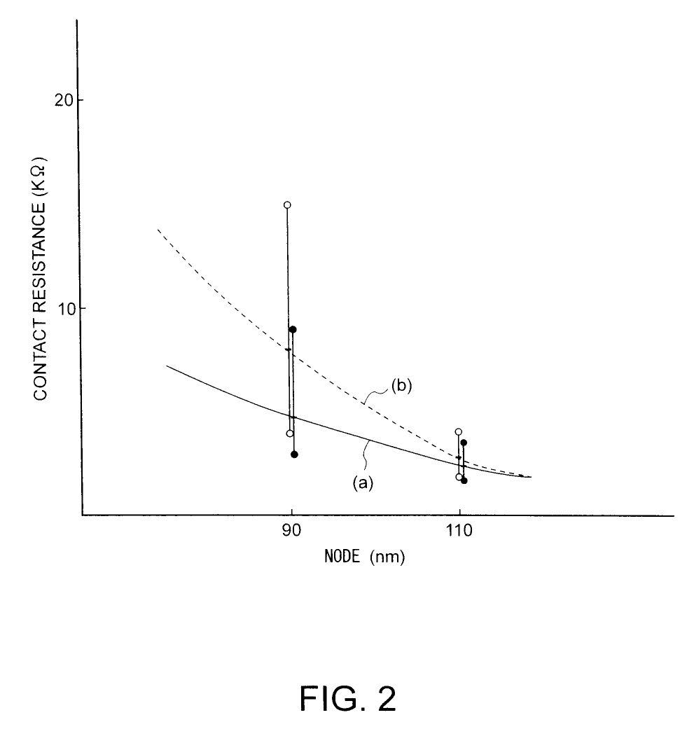

Next, contact characteristics of the memory cell transistor will be described with reference to FIG. 2. FIG. 2 is a graph showing the relationship between the contact resistance and the technology node of the memory cell transistor, in which a solid line (a) in FIG. 2 represents the characteristics of the first embodiment, and a broken line (b) in FIG. 2 represents the characteristics of a comparative example. Herein, the comparative example refers to the example in which a polycrystalline silicon plug formed in the bottom portion of a SAC contact hole of a memory cell transistor has a planar structure.

As shown in FIG. 2, in the comparative example shown by the broken line (b) in FIG. 2, the polycrystalline silicon plug in the SAC contact hole has a planar two-dimensional structure, which in turn leads to a relatively small contact area of the polycrystalline silicon plug with a barrier metal film and a metal plug. Thus, finer technology node causes sharp increases in the contact resistance value of the memory cell transistor and in the variation range of the contact resistance.

For example, if the technology node is 110 nm, the average contact resistance value is approximately 3 kΩ, and the variation range is relatively narrow. As opposed to this, if the technology node is 90 nm, the average contact resistance value increases to approximately 8 kΩ, and the variation range increases in a range from the maximum value of 15 kΩ to the minimum value of 4 kΩ. Although not shown here, technology node finer than 90 nm causes sharp increases in the average contact resistance value and in the variation range of the contact resistance.

On the other hand, in the first embodiment shown by the solid line (a) in FIG. 2, the polycrystalline silicon plug 11 in the SAC contact hole 40 has the U-shaped section structure and thus three-dimensional structure, so that a contact area of the polycrystalline silicon plug 11 with the barrier metal film 12 and the metal plug 13 is larger than that in the comparative example. This enables suppression of the increases in the contact resistance value of the memory cell transistor and in the variation range in the contact resistance, even if the technology node becomes finer.

For example, if the technology node is 110 nm, the average contact resistance value is approximately 2.5 kΩ, and the variation range is relatively narrow. As opposed to this, if the technology node is 90 nm, the average contact resistance value decreases to approximately 4.6 kΩ, the maximum value decreases to 9 kΩ, and the minimum value decreases to 3 kΩ. Thus, the first embodiment enables suppression of the increases in the average contact resistance value and the variation range of the contact resistance, as compared to the comparative example. Although not shown here, even if the technology node becomes finer than 90 nm, the first embodiment enables considerable suppression of the increases in the average contact resistance value and the variation range of the contact resistance, as compared to the comparative example.

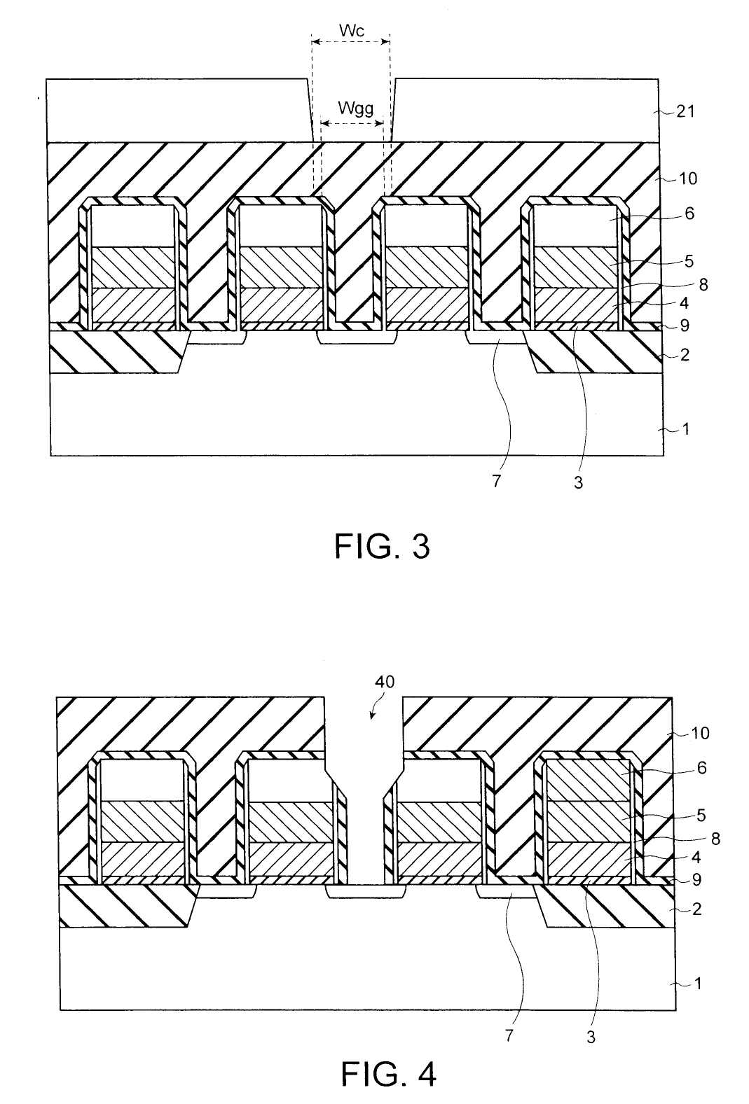

Next, the method of fabricating the semiconductor device will be described with reference to FIGS. 3 to 6. FIGS. 3 to 6 are cross-sectional views for illustrating a fabrication process for the semiconductor device.

As shown in FIG. 3, first, the STI (shallow trench isolation) 2 is buried in the top surface of the semiconductor substrate 1 made of the p type silicon. The gate dielectric film 3, the gate electrode film 4, the metal silicide film 5 and the dielectric film 6 are stacked on the semiconductor substrate 1 and the STI 2. The side wall dielectric film 8 is selectively formed on the side of the stacked structure formed of the gate dielectric film 3, the gate electrode film 4, the metal silicide film 5 and the dielectric film 6. The n type diffusion layer 7 is formed in the top surface of the semiconductor substrate 1 between a gate dielectric film 3 and another gate dielectric film 3 and between the gate dielectric film 3 and the shallow trench isolation (STI) 2. The dielectric film 9 is formed on top of the n type diffusion layer 7, the dielectric film 6 and the STI 2 and on the side of the side wall dielectric film 8. The interlayer dielectric film 10 is formed on the dielectric film 9 in such a manner as to have a planar structure in the top portion of the interlayer dielectric film 10.

Here, the dielectric film 6 is used as a mask member for gate fabrication. A silicon nitride film (SiN film), for example, is used as the dielectric film 6, the side wall dielectric film 8 and the dielectric film 9. Although a TEOS film is used as the interlayer dielectric film 10, a P—SiOC film or the like may be used in place of the TEOS film.

After the formation of the interlayer dielectric film 10, a resist film 21 for the formation of the SAC contact hole 40 is formed by use of a well-known photolithographic technique. Here, a dimension Wc of a contact hole in the resist film 21 is wider than a gap Wgg between the gates of the memory cell transistors, and the end portion of the resist film 21 is formed inwardly of the gate, relative to the end of the gate of the memory cell transistor.

Then, as shown in FIG. 4, the SAC contact hole 40 is formed by etching the interlayer dielectric film 10 and the dielectric film 9 by RIE (reactive ion etching) for example, with the resist film 21 acting as a mask. Here, the dielectric film 6, the side wall dielectric film 8 and the dielectric film 9, which are made of the silicon nitride (SiN) films, have a slower etching rate than the interlayer dielectric film 10 made of the TEOS film. Thus, the side wall dielectric film 8 and the dielectric film 9 remain on the side of the gate of the memory cell transistor. This results in the formation of the SAC contact hole 40 having the funnel-shaped section structure in which the top portion is wider than the bottom portion. The resist film 21 is removed, and then, post-RIE treatment takes place to remove an etching residue or damage caused by the RIE.

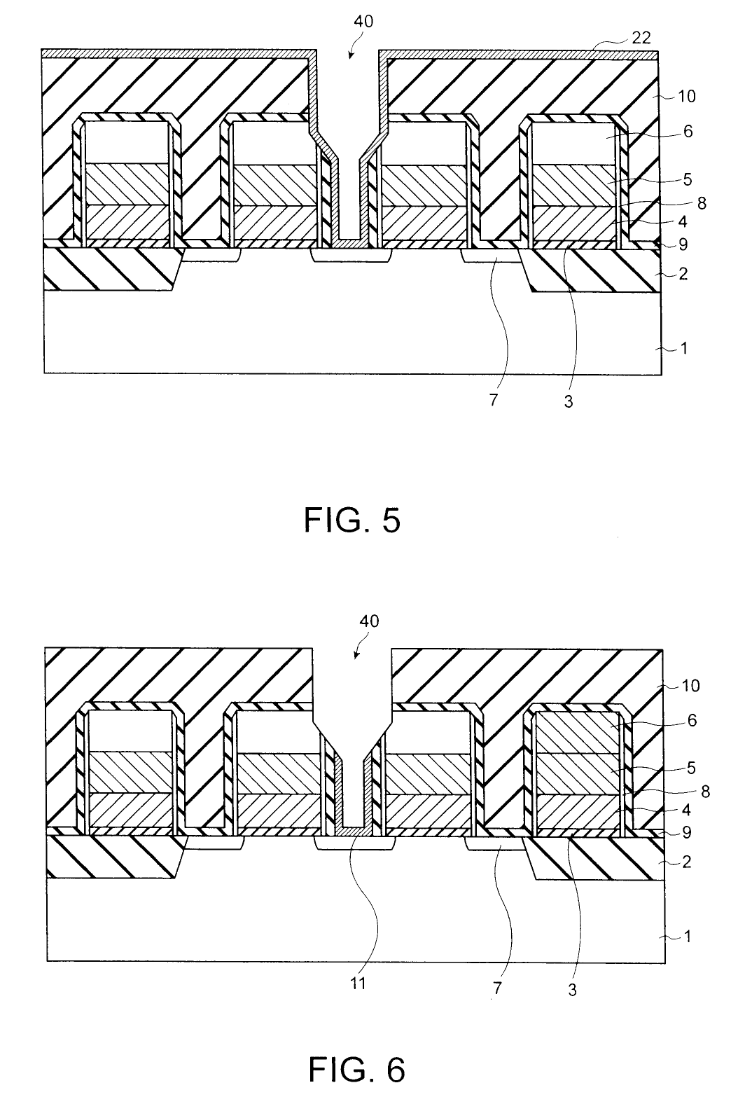

Then, as shown in FIG. 5, a native oxide film on the n type diffusion layer 7 in the SAC contact hole 40 is detached. Thereafter, a polycrystalline silicon film 22 doped with an n type impurity is deposited by use of LP-CVD (low pressure chemical vapor deposition) method, for example. Here, it is preferable that prebaking or the like be performed prior to the deposition of the polycrystalline silicon film 22 in order to prevent a native oxide film from being formed on the n type diffusion layer 7. The prebaking is performed by adding H₂.

Then, as shown in FIG. 6, etch back, for example, is performed throughout the entire area of the polycrystalline silicon film 22 thereby to yield the polycrystalline silicon plug 11 which is formed of the polycrystalline silicon film 22 with the U-shaped section structure, and which remains in the bottom portion of the SAC contact hole 40.

Then, the barrier metal film 12 and the metal plug 13 are formed. Thereafter, the barrier metal film 12 and the metal plug 13 are polished and smoothed by use of CMP (chemical mechanical polishing) process for example, until the surface of the interlayer dielectric film 10 is exposed. After the polishing and smoothing, the barrier metal film 14 and the metal wiring 15 are formed on the metal plug so as to cover the barrier metal film 12 and the metal plug 13.

Here, a tantalum nitride film (TaN film) is used as the barrier metal films 12, 14; however, a titanium nitride film (TiN film), a tungsten nitride film (WN film), tantalum (Ta), niobium (Nb), or the like may be used in place of the TaN film. Although tungsten (W) is used as the metal plug 13, ruthenium (Ru), platinum (Pt), iridium (Ir), or the like may be used in place of tungsten.

Then, the side wall dielectric film 8 is formed so as to cover the side of the gate of the memory cell transistor. After the formation of the metal wiring 15 to be connected to the bit line, an interlayer dielectric film and a wiring layer are formed, and other operations are performed by use of well-known technology to complete the fabrication of the semiconductor device 70 that serves as the DRAM.

According to the semiconductor device in the first embodiment and the method of fabricating the same, as described above, plural insulated gate field effect transistors are formed as the memory cell transistors on the semiconductor substrate 1. The n type diffusion layer 7 to serve as a source or drain of the insulated gate field effect transistor is formed in the top surface of the semiconductor substrate 1 between the insulated gate field effect transistors. The SAC contact hole 40 is formed between the gates of the insulated gate field effect transistors. The side portion of the SAC contact hole 40 is separated from the gate of the insulated gate field effect transistor by the side wall dielectric film 8 and the dielectric film 9. The polycrystalline silicon plug 11 having the U-shaped section structure is formed in the bottom portion of the SAC contact hole 40. The barrier metal film 12 is formed on the polycrystalline silicon plug 11. The metal plug 13 is buried in the SAC contact hole 40 and provided on the barrier metal film 12 so as to cover the SAC contact hole 40.

Thus, the contact area of the polycrystalline silicon plug 11 with the barrier metal film 12 and the metal plug 13 can become larger than that in the case where the polycrystalline silicon plug has the planar structure. Therefore, this enables reduction in the contact resistance value of the memory cell transistor of the semiconductor device 70 and in the variation range of the contact resistance.

Incidentally, in the first embodiment, the invention is applied to the contact plug of the memory cell transistor of the DRAM; however, the invention may be applied to a contact plug for a NOR type or NAND type flash memory, a logic device, or the like. Also, the polycrystalline silicon plug 11 having the U-shaped section structure is formed in the bottom portion of the SAC contact hole 40 of the memory cell transistor; however, an amorphous silicon plug having the U-shaped section structure may be formed in place of the polycrystalline silicon plug.

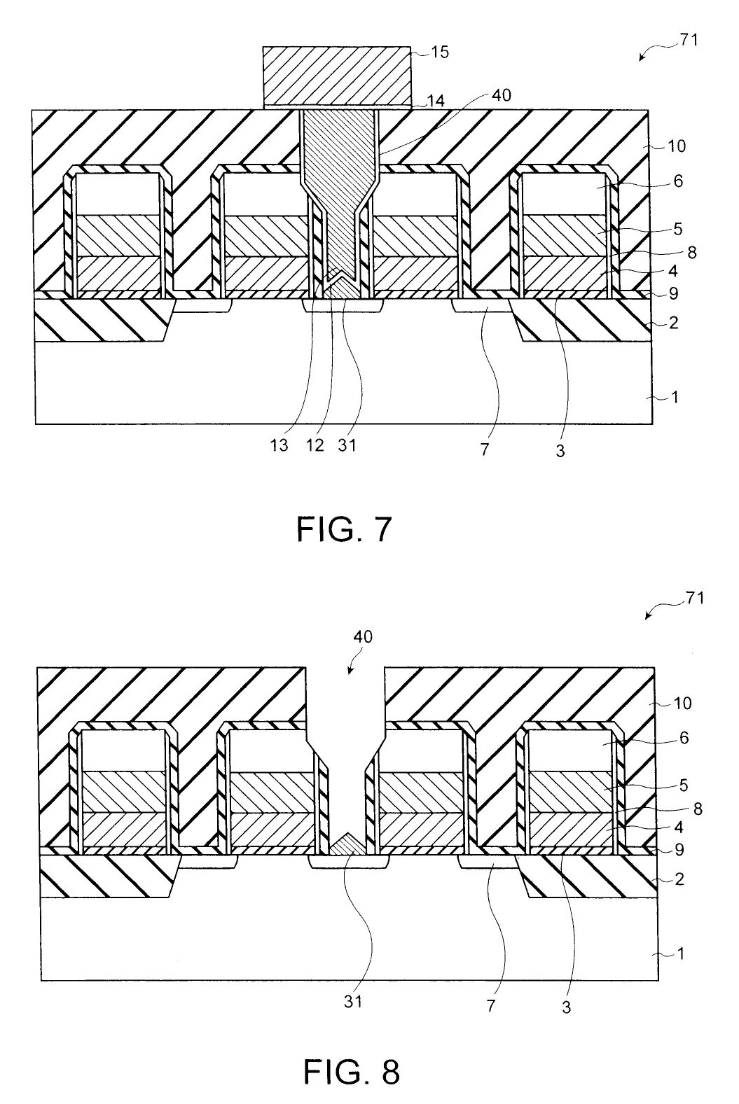

A semiconductor device according to a second embodiment of the invention and a method of fabricating the same will be described with reference to the drawings. FIG. 7 is a cross-sectional view showing the semiconductor device. In the second embodiment, a silicon plug having a pyramid-shaped section structure is selectively formed in a bottom portion of a SAC contact hole of a memory cell transistor.

Hereinafter, the same portions as those of the first embodiment are denoted by the same reference numerals. Description of the same portions will be omitted, and description will be given only with regard to different portions.

As shown in FIG. 7, a semiconductor device 71 includes plural memory cell transistors formed on the semiconductor substrate 1. The semiconductor device 71 is a DRAM provided with the plural memory cell transistors and with a peripheral circuit and an input/output circuit (not shown). MIS transistors are used as transistors to form the peripheral circuit and the input/output circuit. An n channel type MIS transistor is used as the memory cell transistor.

In the semiconductor device 71, the semiconductor substrate 1 made of p type silicon is used, and has a (100) plane direction. The formation of the SAC contact hole 40 is accomplished by etching the top portions of the dielectric film 6, the side wall dielectric film 8 and the dielectric film 9. The dielectric film 9 on the n type diffusion layer 7 is etched away. The SAC contact hole 40 is formed between the gates of the memory cell transistors, and has the funnel-shaped section structure whose top portion is wider than the bottom portion.

The contact plug constructed of a silicon plug 31, the barrier metal film 12 and the metal plug 13 is buried in the SAC contact hole 40. The silicon plug 31 is doped with an n type impurity and is formed on the n type diffusion layer 7 immediately under the SAC contact hole 40. The silicon plug 31 has a pyramid-shaped section structure. The barrier metal film 12 is formed on the silicon plug 31 and on the side of the SAC contact hole 40. The metal plug 13 is buried in the SAC contact hole 40 and provided on the barrier metal film 12 so as to cover the SAC contact hole 40.

Next, the method of fabricating the semiconductor device will be described with reference to FIG. 8. FIG. 8 is a cross-sectional view for illustrating a fabrication process for the semiconductor device. Here, since fabrication steps until the formation of the SAC contact hole 40 are the same as those of the first embodiment, illustration and description of the same steps will be omitted.

After the formation of the SAC contact hole 40, as shown in FIG. 8, a native oxide film on the n type diffusion layer 7 immediately under the SAC contact hole 40 is detached. After the detachment of the native oxide film, silicon doped with an n type impurity is grown by selective epitaxial growth (SEG) by use of LP-CVD method, for example. The conditions of the selective epitaxial growth are that dichlorosilane (SiH₂Cl₂), hydrogen chloride (HCl), doping gas, and hydrogen (H₂) are used as a gas seed. A growth temperatures lies between 600 and 1000° C. and is preferably of the order of 800° C. Prior to the selective epitaxial growth, prebaking is performed by adding H₂ at approximately 1000° C. for example, in order to prevent a native oxide film from being formed on the n type diffusion layer 7. Here, the dichlorosilane (SiH₂Cl₂) is used as a reactive gas. The hydrogen chloride (HCl) is used as an accelerating gas for the selective epitaxial growth. The hydrogen (H₂) is used as a carrier gas. Phosphine (PH₃), for example, is used as the doping gas.

By the selective epitaxial growth, the silicon is epitaxially grown only on the silicon substrate, rather than on the dielectric film. Since the semiconductor substrate 1 made of the p type silicon has the (100) plane direction, a facet of the semiconductor substrate 1, serving as a growth surface, is a (110) plane direction, so that the silicon plug 31 having the pyramid-shaped section structure is formed on the n type diffusion layer 7.

Then, the barrier metal film 12 and the metal plug 13 are formed on the silicon plug 31. The subsequent steps are the same as those of the first embodiment, and illustration and description of the same processes will be omitted.

Here, the silicon plug 31 in the SAC contact hole 40 has the three-dimensional pyramid-shaped section structure, so that a contact area of the silicon plug 31 with the barrier metal film 12 and the metal plug 13 is approximately 1.6 times larger than that in the comparative example of the first embodiment. Thus, the contact resistance value of the memory cell transistor is reduced to approximately ( 1/1.6), as compared to that in the comparative example of the first embodiment.

According to the semiconductor device in the second embodiment and the method of fabricating the same, as described above, plural insulated gate field effect transistors are formed as the memory cell transistors on the semiconductor substrate 1. The n type diffusion layer 7 to serve as the source or drain of the insulated gate field effect transistor is formed in the top surface of the semiconductor substrate 1 between the insulated gate field effect transistors. The SAC contact hole 40 is formed between the gates of the insulated gate field effect transistors. The side portion of the SAC contact hole 40 is separated from the gate of the insulated gate field effect transistor by the side wall dielectric film 8 and the dielectric film 9. The silicon plug 31 having the pyramid-shaped section structure is formed in the bottom portion of the SAC contact hole 40. The barrier metal film 12 is formed on the silicon plug 31. The metal plug 13 is buried in the SAC contact hole 40 and provided on the barrier metal film 12 so as to cover the SAC contact hole 40.

Thus, the contact area of the silicon plug 31 with the barrier metal film 12 and the metal plug 13 can become larger than that in the case where the silicon plug or the polycrystalline silicon plug has the planar structure. Therefore, this enables reduction in the contact resistance value of the memory cell transistor of the semiconductor device 71 and in the variation range of the contact resistance.

Incidentally, in the second embodiment, the dichlorosilane (SiH₂Cl₂) and the hydrogen chloride (HCl) are used for the selective epitaxial growth of the silicon; however, tetrachlorosilane (SiCl₄), disilane (Si₂H₆), or the like may be used for the selective epitaxial growth of the silicon.

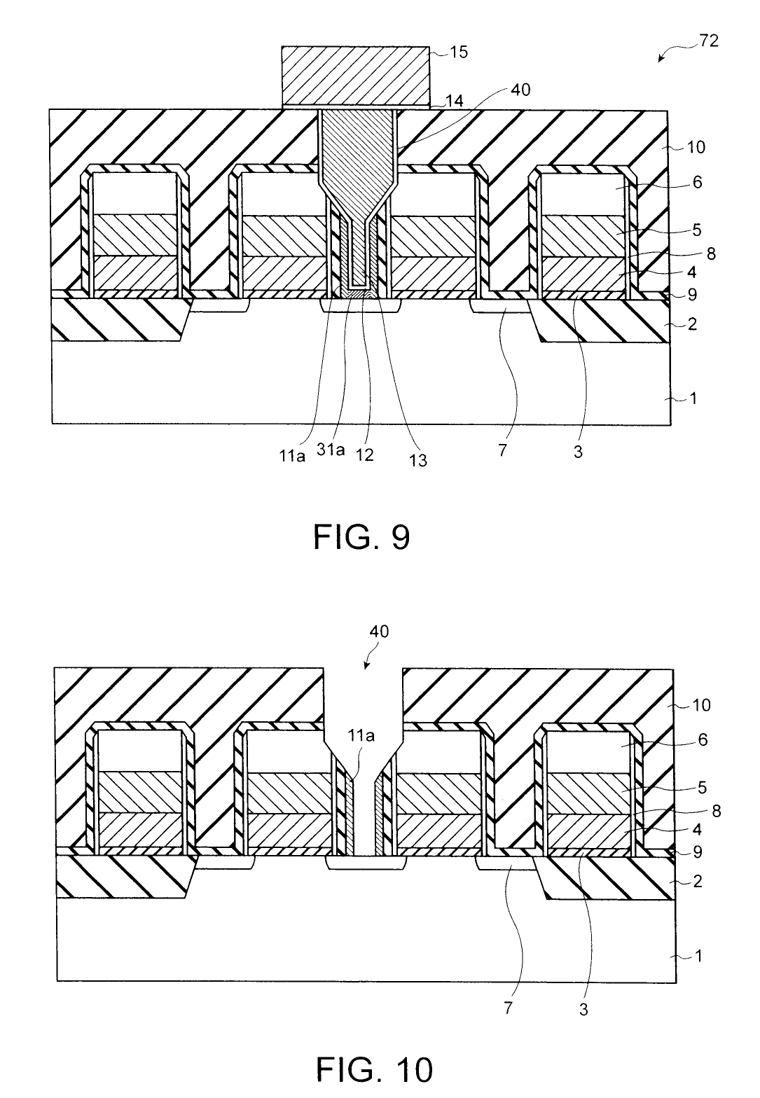

A semiconductor device according to a third embodiment of the invention and a method of fabricating the same will be described with reference to the drawings. FIG. 9 is a cross-sectional view showing the semiconductor device. In the third embodiment, a silicon plug is formed in a bottom portion of a SAC contact hole of a memory cell transistor, and a polycrystalline silicon plug to be connected to the silicon plug is formed on the sides of the bottom portion of the SAC contact hole of the memory cell transistor.

Hereinafter, the same portions as those of the first embodiment are denoted by the same reference numerals. Description of the same portions will be omitted, and description will be given only with regard to different portions.

As shown in FIG. 9, a semiconductor device 72 includes plural memory cell transistors formed on the semiconductor substrate 1. The semiconductor device 72 is a DRAM provided with the plural memory cell transistors and with a peripheral circuit and an input/output circuit (not shown). MIS transistors are used as transistors to form the peripheral circuit and the input/output circuit. An n channel type MIS transistor is used as the memory cell transistor.

In the semiconductor device 72, the SAC contact hole 40 is formed between the gates of the memory cell transistors. The formation of the SAC contact hole 40 is accomplished by etching the top portions of the dielectric film 6, the side wall dielectric film 8 and the dielectric film 9. The dielectric film 9 on the n type diffusion layer 7 is etched away. The SAC contact hole 40 has the funnel-shaped section structure whose top portion is wider than the bottom portion.

The contact plug constructed of a polycrystalline silicon plug 11a, a silicon plug 31a, the barrier metal film 12 and the metal plug 13 is buried in the SAC contact hole 40. The polycrystalline silicon plug 11a is doped with an n type impurity. The polycrystalline silicon plug 11a is formed on the sides of the bottom portion of the SAC contact hole 40. The silicon plug 31a is connected to the polycrystalline silicon plug 11a. The silicon plug 31a is doped with an n type impurity. The silicon plug 31a is formed in the bottom portion of the SAC contact hole 40. The polycrystalline silicon plug 11a and the silicon plug 31a function as a single plug and have the U-shaped section structure as a whole. The barrier metal film 12 is formed on the silicon plug 31a and the polycrystalline silicon plug 11a. The metal plug 13 is buried in the SAC contact hole 40 and provided on the barrier metal film 12 so as to cover the SAC contact hole 40.

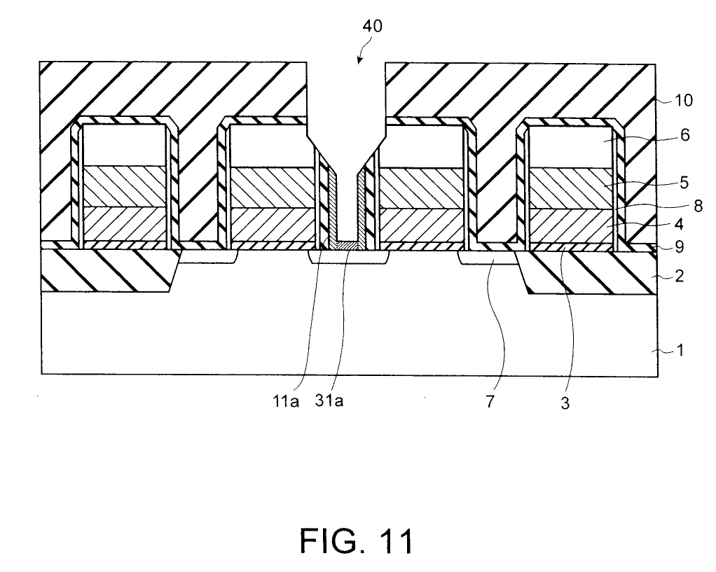

Next, the method of fabricating the semiconductor device will be described with reference to FIGS. 10 and 11. FIGS. 10 and 11 are cross-sectional views for illustrating a fabrication process for the semiconductor device. Here, since fabrication steps until the formation of the SAC contact hole 40 are the same as those of the first embodiment, illustration and description of the same steps will be omitted.

After the formation of the SAC contact hole 40, as shown in FIG. 10, a native oxide film on the n type diffusion layer 7 immediately under the SAC contact hole 40 is detached. After the detachment of the native oxide film, a polycrystalline silicon film doped with an n type impurity is formed by use of LP-CVD method, for example. After that, etch back is performed throughout the entire area of the polycrystalline silicon film thereby to etch away the polycrystalline silicon film in the bottom portion of the SAC contact hole 40 and on the interlayer dielectric film 10. As a result, the polycrystalline silicon plug 11a is formed with the polycrystalline silicon film remaining only in the sidewall portion.

Then, as shown in FIG. 11, epitaxial growth takes place. The conditions of the epitaxial growth are that dichlorosilane (SiH₂Cl₂), doping gas, and hydrogen (H₂) are used as a gas seed. Prior to the epitaxial growth, prebaking is performed by adding H₂ gas in order to prevent a native oxide film from being formed on the n type diffusion layer 7. By the epitaxial growth, an epitaxial film is grown in the bottom portion of the SAC contact hole 40, thereby to form the silicon plug 31a.

Then, the barrier metal film 12 and the metal plug 13 are formed on the polycrystalline silicon plug 11a and the silicon plug 31a. The subsequent steps are the same as those of the first embodiment, and illustration and description of the same processes will be omitted.

Here, the plug having the three-dimensional U-shaped section structure, constructed of the polycrystalline silicon plug 11a and the silicon plug 31a, is formed in the SAC contact hole 40. This increases a contact area of the plug with the barrier metal film 12 and the metal plug 13, thus reducing the contact resistance value of the memory cell transistor and the variation range of the contact resistance, as compared to the comparative example of the first embodiment.

According to the semiconductor device in the third embodiment and the method of fabricating the same, as described above, plural insulated gate field effect transistors are formed as the memory cell transistors on the semiconductor substrate 1. The n type diffusion layer 7 to serve as the source or drain of the insulated gate field effect transistor is formed in the top surface of the semiconductor substrate 1 between the insulated gate field effect transistors. The SAC contact hole 40 is formed between the gates of the insulated gate field effect transistors. The side portion of the SAC contact hole 40 is separated from the gate of the insulated gate field effect transistor by the side wall dielectric film 8 and the dielectric film 9. The polycrystalline silicon plug 11a is formed on the sides of the bottom portion of the SAC contact hole 40. The silicon plug 31a to be connected to the polycrystalline silicon plug 11a is formed in the bottom portion of the SAC contact hole 40. The polycrystalline silicon plug 11a and the silicon plug 31a constitute the plug having the U-shaped section structure. The barrier metal film 12 is formed on the polycrystalline silicon plug 11a and the silicon plug 31a. The metal plug 13 is buried in the SAC contact hole 40 and provided on the barrier metal film 12 so as to cover the SAC contact hole 40.

Thus, the contact area of the plug with the barrier metal film 12 and the metal plug 13 can become larger than that in the case where the polycrystalline silicon plug has the planar structure. Therefore, this enables reduction in the contact resistance value of the memory cell transistor of the semiconductor device 72 and in the variation range of the contact resistance.

The invention is not limited to the above embodiments, and various changes may be made in the invention without departing from the spirit and scope of the invention.

For example, in the embodiments, the invention is applied to the contact plug of the DRAM or flash memory; however, the invention may be applied to a contact plug for a logic device having a logic circuit or a sequential circuit, a system LSI, a SoC (system on a chip), or the like.

What is claimed is:

1. A semiconductor device, comprising:
a first insulated gate field effect transistor formed on a semiconductor substrate of a first conductive type;
a second insulated gate field effect transistor formed on the semiconductor substrate and having a gate being adjacent to a gate of the first insulated gate field effect transistor;
a semiconductor layer of a second conductive type formed in a surface region of the semiconductor substrate between the gates of the first and the second insulated gate field effect transistors as a source or a drain of the first and the second insulated gate field effect transistors; and
a contact plug composed of a polycrystalline silicon plug, a barrier metal film and a metal plug and formed in a contact hole, a side portion of the contact plug being separated from the gates of the first and the second insulated gate field effect transistors by a dielectric film,
wherein the polycrystalline silicon plug has a U-shaped section structure and is formed in a bottom portion of the contact hole, and wherein the barrier metal film is formed on the polycrystalline silicon plug, and wherein the metal plug is formed on the barrier metal film.

2. The semiconductor device according to claim 1, wherein the contact hole is a SAC contact hole having a funnel-shaped section structure whose top portion is wider than the bottom portion.

3. The semiconductor device according to claim 2, wherein the polycrystalline silicon plug is buried in a bottom portion of the funnel-shaped section structure.

4. The semiconductor device according to claim 3, wherein the barrier metal film is formed on the polycrystalline silicon plug and a side portion of the contact hole.

5. The semiconductor device according to claim 1, wherein the barrier metal film is at least one of a TaN film, a TiN film, a WN film, a Ta film or a Nb film.

6. The semiconductor device according to claim 1, wherein the metal plug is constituted by at least one of W(tungsten), Ru(ruthenium), Pt(platinum) or Ir(iridium).

7. The semiconductor device according to claim 1, wherein the first and the second insulated gate field effect transistors are used as a memory cell transistor.

8. The semiconductor device according to claim 1, wherein the first and the second insulated gate field effect transistors are a MOSFET or a MISFET.

9. A semiconductor device, comprising:
a first insulated gate field effect transistor formed on a semiconductor substrate of a first conductive type;
a second insulated gate field effect transistor formed on the semiconductor substrate and having a gate being adjacent to a gate of the first insulated gate field effect transistor;
a semiconductor layer of a second conductive type formed in a surface region of the semiconductor substrate between the gates of the first and the second insulated gate field effect transistors as a source or a drain of the first and the second insulated gate field effect transistors; and
a contact plug composed of a silicon plug, a barrier metal film and a metal plug in a contact hole, a side portion of the contact plug being separated from the gates of the first and the second insulated gate field effect transistors by a dielectric film,
wherein the silicon plug has a pyramid-shaped section structure and is formed in a bottom portion of the contact hole, and wherein the barrier metal film is formed on the silicon plug, and wherein the metal plug is formed on the barrier metal film.

10. The semiconductor device according to claim 9, wherein the contact hole is a SAC contact hole having a funnel-shaped section structure whose top portion is wider than the bottom portion.

11. The semiconductor device according to claim 9, wherein the barrier metal film is formed on the silicon plug and a side portion of the SAC contact hole.

12. The semiconductor device according to claim 9, wherein the semiconductor substrate has a (100) plane direction, and a slope of the silicon plug has a (111) plane direction.

13. The semiconductor device according to claim 9, wherein the first and the second insulated gate field effect transistors are used as a memory cell transistor.

14. A method of fabricating a semiconductor device, comprising:
forming a side wall dielectric film on a side of gates of a first and a second insulated gate field effect transistors;
forming a dielectric film on gates of the first and the second insulated gate field effect transistors, a side of the side wall dielectric film and a source or a drain of the first and the second insulated gate field effect transistors;
forming a interlayer dielectric film on the dielectric film;
forming a contact hole between a gate of the first insulated gate field effect transistor and a gate of the second insulated gate field effect transistor being adjacent to the first insulated gate field effect transistor;
forming a polycrystalline silicon film in a bottom portion of the contact hole and a side of the contact hole and on the interlayer dielectric film;
forming a polycrystalline silicon film having a U-shaped section structure in a bottom portion of the contact hole as a polycrystalline silicon plug, by removing a portion of the polycrystalline silicon film formed on the interlayer dielectric film and another portion of the polycrystalline silicon film formed in a upper portion of the contact hole using a etch back process;
forming a barrier metal film on the polycrystalline silicon plug; and
burying a metal plug on the barrier metal film so that covering on the contact hole.

15. The method according to claim 14, wherein the contact hole is a SAC contact hole having a funnel-shaped section structure whose top portion is wider than the bottom portion.

16. The method according to claim 14, wherein the dielectric film is a SiN film.

17. The method according to claim 14, wherein the interlayer dielectric film is a TEOS film or a P—SiOC film.

18. The method according to claim 14, wherein the polycrystalline silicon plug and the barrier metal film are polished and smoothed using a CMP process.
